(19) United States
(12) Patent Application Publication
(10) Pub. No.: US 2001/0010476 A1
(43) Pub. Date: Aug. 2, 2001

(54) Protecting apparatus for protecting the isolation circuit between different power domains

(76) Inventors: Chih-Hsien Weng, Junan Jen (TW); Cheng-Yuan Wu, Putz City (TW)

Correspondence Address: RABIN & CHAMPAGNE, PC, 1101 14TH STREET, NW, SUITE 500, WASHINGTON, DC, 20005, US

(21) Appl. No.: 09/764,086

(22) Filed: Jan. 19, 2001

(30) Foreign Application Priority Data
Feb. 1, 2000 (TW) 89101715

(51) Int. Cl. H03L 5/00

(52) U.S. Cl. 327/314

(57) ABSTRACT

A protecting apparatus for protecting an isolation circuit between different power domains receives a first signal, which is a level-changeable signal, from a first power domain and outputs a second signal to the isolation circuit. The apparatus includes an anti-noise circuit and a signal shaper. The anti-noise circuit receives the first signal. The signal shaper receives the output of the anti-noise circuit and outputs the second signal to the isolation circuit.

This application incorporates by reference Taiwanese application Serial No. 89101715, Filed Feb. 1, 2000.

### BACKGROUND OF THE INVENTION

1. Field of the Invention

The invention relates in general to a protecting apparatus for protecting the isolation circuit between different power domains, and more particularly to a protecting apparatus, which effectively isolates the noise and protects the isolation circuit between different power domains in an integrated circuit (IC).

2. Description of the Related Art

In the design of IC products, power management is a basic consideration. Reducing the power consumption of IC products can reduce the total power consumption used in the apparatus on which the IC products are installed. Thus, the total usage time of the power cell installed in the apparatus can be increased. This is an important appeal for portable apparatuses such as a portable computer.

The power-saving mode of energy management is illustrated as follows. When the system is idle, the main circuit of the IC stays in the power-on status while other circuits are in the power-off status. In this way, the power consumption of IC products can be effectively reduced.

In an IC product provided with the ability for power management, there are different power domains. When the status of a power domain is changed, unstable signals such as noise may be generated and propagated to other power domains. This affects the operating statuses of other power domains and, even worse, may destroy the circuits.

As a result, processing the signals between different power domains becomes an important topic. How to avoid unstable signals such as noise to propagate from a power-off domain to a power-on domain and how to protect the circuits for stable operations are being researched.

Referring to FIG. 1, the conventional method to achieve the above is illustrated. As shown in FIG. 1, an AND gate logic circuit 100, for example, an AND gate, is used as an isolation circuit between different power domains. Besides, a control signal CTL is used for enabling the isolation circuit.

In FIG. 1, power domain I represents a power-off domain and power domain II represents a power-on domain. Signal SIG_I is propagated from power domain I to power domain II. Signal SIG_I and control signal CTL are inputted to AND gate logic circuit 100 to generate the signal SIG_II. The AND gate logic circuit 100 is in the power domain II as shown in FIG. 1 therefore, the AND gate logic circuit 100 is power-on.

Referring to FIG. 2, which illustrates a timing diagram of control signal CTL, signals SIG_I, and SIG_II. In FIG. 2, region A is a power-on region while region B is a power-off region. The control signal CTL is changed from high level to low level before the power of power domain I is turned off After the power domain I is changed to power off, since signal SIG_I is inputted to the AND gate logic circuit 100 along with the control signal CTL, the output signal SIG_II is in low-level in spite of the fact that signal SIG_I may include noise. As a result, after the power of power domain I is turned off, signal SIG_II is not affected by noises from power domain I; that is, no noise from power domain I enters power domain II after the power of power domain I is turned off.

The AND gate logic circuit 100 can be implemented by other ways. For example, a plurality of NOR gates can be used to achieve the function of the AND gate logic circuit 100. The details are illustrated as follows.

The function of the circuit shown in FIG. 1 can be represented by the following equation, wherein the symbol “ ●” denotes the AND operation.

S_II=SIG_I ●CTL (1)

After taking the complement of equation (1), equation (2) is then obtained, wherein the symbol “+” denotes the OR operation.

SIG_II′=(SIG_I′+CTL′)′ (2)

According to equation (2), the function of the AND gate logic circuit 100 can be implemented by a NOR gate and three invertors. For illustration's sake, the AND gate is taken for example.

There are some disadvantages of the conventional technique mentioned above. First, when the power is turned on or turned off, the rising or the falling process of voltage is irregular and slow. Referring to FIG. 3, the curved line on the left is the timing diagram of the rising voltage when the power is turned on while the curved line on the right is the timing diagram of the falling voltage when the power is turned off. In FIG. 3, the processes of turning the power on or off are irregular and slow; and accordingly the AND gate logic circuit 100 stays in the linear region and has extra leakage current.

Second, when the power is turned off in the power domain I, there are some noise from the power domain I transmitted to the AND gate logic circuit 100, which causes carrier migration phenomenon of the metal oxide semiconductor (MOS) of the AND gate logic circuit 100. This carrier migration phenomenon decreases the lifetime of the MOS, and accordingly decreases the lifetime of the IC products.

### SUMMARY OF THE INVENTION

It is therefore an object of the invention to provide a protecting apparatus for protecting the isolation circuit between different power domains. The protecting apparatus effectively makes the isolation circuit between different power domains have lower leakage current, better anti-noise characteristic, and longer lifetime. As a result, the quality of IC products is improved.

The invention achieves the above-identified objects by providing a protecting apparatus for protecting an isolation circuit between different power domains. The protecting apparatus receives a first signal, which is a level-changeable signal, from a first power domain and outputs a second signal to the isolation circuit. The apparatus includes an anti-noise circuit and a signal shaper. The first signal is received by the anti-noise circuit which then outputs a signal to the signal shaper. The signal shaper then outputs the second signal to the isolation circuit.

The invention achieves the above-identified objects by providing an isolation circuit between different power domains. The isolation circuit receives a first signal, which is a level-changeable signal, from a first power domain and outputs a second signal to a second power domain. The apparatus includes an anti-noise circuit, a signal shaper, and an AND gate logic circuit. The anti-noise circuit receives the first signal and the signal shaper receives the output of the anti-noise circuit. The AND gate logic circuit receives the output of the signal shaper and a control signal and outputs the second signal to the second power domain, wherein the second signal is in low level when the control signal is in low level.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 (Prior Art) is the circuit diagram of the conventional isolation circuit between different power domains;

FIG. 2 (Prior Art) is the timing diagram of the signals shown in FIG. 2;

FIG. 3 (Prior Art) is the timing diagram of the voltages when the power is turned on and off;

FIG. 4 (Prior Art) is the timing diagram of a noise;

FIG. 5 is a circuit diagram of the protecting apparatus for protecting the isolation circuit between different power domains according to the invention;

FIG. 6 is a timing diagram of the input and output signals of the Schmitt trigger shown in FIG. 5;

FIG. 7 is a timing diagram of the input and output signals of the anti-noise circuit shown in FIG. 5; and

FIG. 8 is a timing diagram of the input and output signals of the anti-noise circuit shown in FIG. 5 according to another example of the invention.

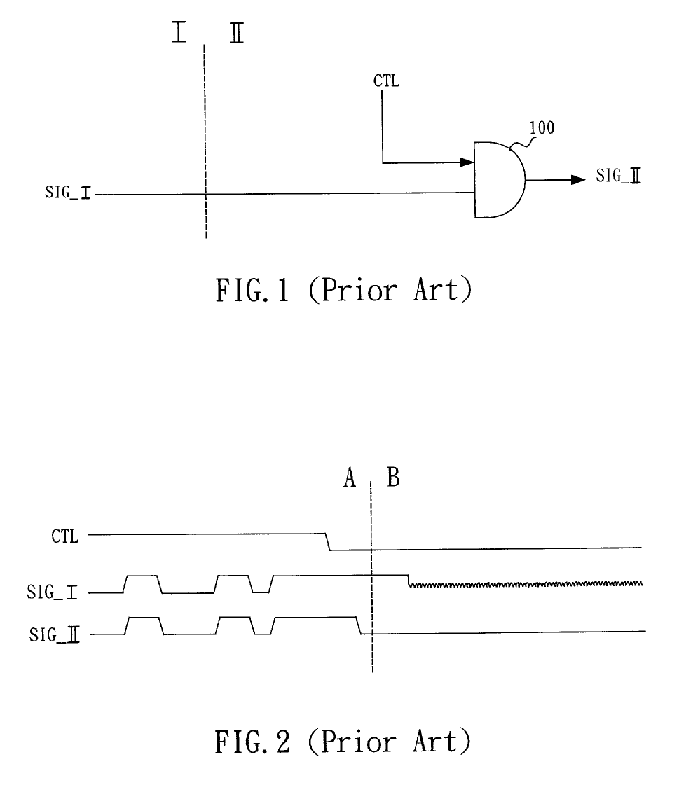

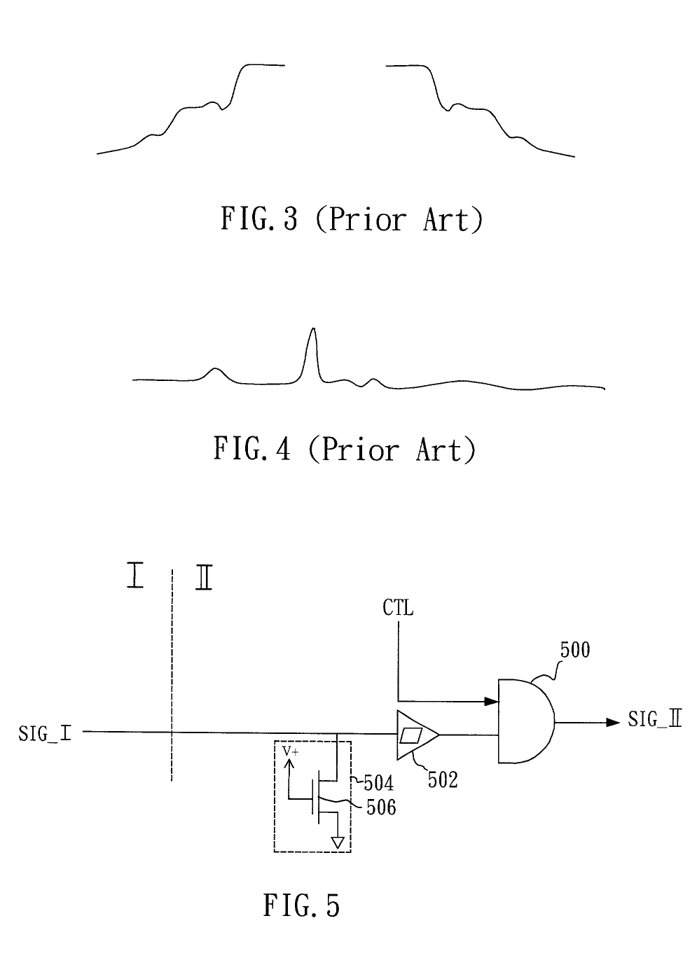

### DESCRIPTION OF THE PREFERRED EMBODIMENT

FIG. 5 depicts a circuit diagram of the protecting apparatus for protecting the isolation circuit between different power domains according to the invention. In FIG. 5, an AND gate logic circuit 500 is taken as an example of the isolation circuit between different power domains. There are other ways to implement the function of the AND gate logic circuit 500 such as using NOR gates.

The protecting apparatus for protecting the isolation circuit between different power domains according to the invention includes a Schmitt trigger 502 and an anti-noise circuit 504. The Schmitt trigger 502 is a bi-stable circuit. When a signal whose amplitude is greater than the trigger level of the Schmitt trigger 502 is inputted, a precise rectangular wave of fixed amplitude is outputted. As a result, the Schmitt trigger 502 can be used as a signal shaper.

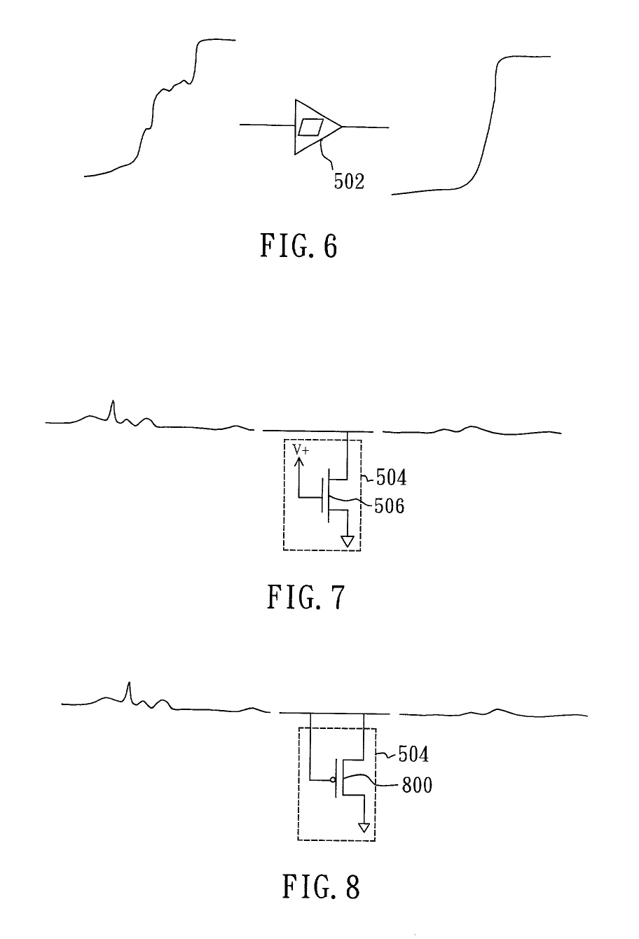

Referring to FIG. 6, the process for the input signal in the left changing from low level to high level is irregular and slow. Through the Schmitt trigger 502, a sharper signal is outputted. Consequently, the protecting apparatus for protecting the isolation circuit between different power domains according to the invention can effectively reduce the leakage current by the usage of the Schmitt trigger 502.

On the other hand, the anti-noise circuit 504 is implemented by an N-type MOS (NMOS) 506. The drain of the NMOS 506 is connected to the input of the AND gate logic circuit 500 while the source thereof is connected to the low level of the system such as the ground level. Moreover, the gate of the NMOS 506 is connected to the power V+ of the power domain II. By adjusting the L/W ratio of the NMOS 506, the NMOS 506 acts as a resistor with an equivalent resistance of, for example, 100KΩ. The NMOS 506 is used to filter out noise, which may be a level-changeable signal between a relative low level and high level, transmitted from the power domain I and prevent noise from inputting to the AND gate logic circuit 500 in the power domain II. This prevents noise from decreasing the lifetime of the MOS in the AND gate logic circuit 500. Referring to FIG. 7, the anti-noise circuit 504 receives the noise in the left and outputs a signal without the noise.

There are other ways to implement the invention. For example, the isolation circuit between different power domains can be implemented by NOR gates. Moreover, referring to FIG. 8, the anti-noise circuit 504 is implemented by P-type MOS (PMOS) 800, which is used to filter out noise for protecting the isolation circuit. The gate and the drain of the PMOS 800 are connected to the input of the AND gate logic circuit 500 while the source is connected to the low level of the system such as the ground level. As shown in FIG. 8, the anti-noise circuit 504 receives a noise in the left and outputs a signal without the noise in the right side of FIG. 8.

According to the characteristic of the PMOS 800, the anti-noise circuit 504 turns off automatically when the isolation circuit between different power domains is in normal mode rather than in the power-saving mode; that is, when both power domains I and II are on. This is because when the gate of the PMOS 800 is positive, the PMOS 800 is off. As a result, there is no leakage current of the anti-noise circuit 504. This is the advantage of the PMOS 800 over the NMOS 506 as an anti-noise circuit.

In summary, the protecting apparatus for protecting the isolation circuit between different power domains according to the invention utilizes a Schmitt trigger and an anti-noise circuit to effectively achieve the characteristics of lower leakage current, better anti-noise characteristic and longer lifetime for protecting the isolation circuit between different power domains. Thus, the problem of the leakage current and the shorter lifetime in the conventional technique can be effectively solved, particularly when the noise is a level-changeable signal.

While the invention has been described by way of example and in terms of the preferred embodiment, it is to be understood that the invention is not limited to the disclosed embodiment. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A protecting apparatus for protecting an isolation circuit between different power domains, receiving a first signal from a first power domain and outputting a second signal to the isolation circuit, wherein the first signal is a level-changeable signal, the protecting apparatus comprising:
an anti-noise circuit, for receiving the first signal; and
a signal shaper, for receiving the output of the anti-noise circuit and outputting the second signal to the isolation circuit.

2. The protecting apparatus according to claim 1, wherein the signal shaper is a Schmitt trigger.

3. The protecting apparatus according to claim 1, wherein the isolation circuit is an AND gate logic circuit, for receiving a control signal and the second signal and outputting a third signal to the second power domain.

4. The protecting apparatus according to claim 3, wherein the AND gate logic circuit is an AND gate.

5. The protecting apparatus according to claim 1, wherein the anti-noise circuit is a resistor.

6. The protecting apparatus according to claim 1, wherein the anti-noise circuit is implemented by a P-type metal oxide semiconductor (PMOS), wherein the drain and the gate of the PMOS are connected to the first signal.

7. The protecting apparatus according to claim 1, wherein the anti-noise circuit is implemented by an N-type metal oxide semiconductor (NMOS), wherein the drain of the NMOS is connected to the first signal.

8. An isolation circuit between different power domains, for receiving a first signal from a first power domain and outputting a second signal to a second power domain, wherein the first signal is a level-changeable signal, the isolation circuit comprising:
an anti-noise circuit, for receiving the first signal;
a signal shaper, for receiving the output of the anti-noise circuit; and
an AND gate logic circuit, for receiving the output of the signal shaper and a control signal and outputting the second signal to the second power domain, wherein the second signal is in low level when the control signal is in low level.

9. The isolation circuit according to claim 8, wherein the anti-noise circuit is a resistor.

10. The isolation circuit according to claim 8, wherein the anti-noise circuit is implemented by a P-type metal oxide semiconductor (PMOS), wherein the drain and the gate of the PMOS are connected to the first signal.

11. The isolation circuit according to claim 8, wherein the anti-noise circuit is implemented by an N-type metal oxide semiconductor (NMOS), wherein the drain of the NMOS is connected to the first signal.

12. The isolation circuit according to claim 8, wherein the signal shaper is a Schmitt trigger.

13. The isolation circuit according to claim 8, wherein the AND gate logic circuit is an AND gate.

14. The isolation circuit according to claim 8, wherein the AND gate logic circuit is a NOR gate.
